(19) United States
(12) Patent Application Publication
(10) Pub. No.: US 2010/0210093 A1
(43) Pub. Date: Aug. 19, 2010

(54) METHOD FOR FORMING SILICON-BASED THIN FILM BY PLASMA CVD METHOD

(76) Inventors: Kenji Kato, Kyoto (JP); Eiji Takahashi, Kyoto (JP)

Correspondence Address: Cheng Law Group, PLLC, 1100 17th Street, N.W., Suite 503, Washington, DC, 20036, US

(21) Appl. No.: 12/513,362

(22) PCT Filed: Oct. 29, 2007
(86) PCT No.: PCT/JP2007/070994

§ 371 Date: Feb. 3, 2010

(30) Foreign Application Priority Data
Nov. 9, 2006 (JP) 2006-303676

(51) Int. Cl. H01L 21/205

(52) U.S. Cl. 438/488; 257/E21.102

(57) ABSTRACT

In the method for forming a silicon-based thin film by the plasma CVD method using high-frequency excitation, a polycrystalline silicon-based thin film having high degree of crystallization is formed relatively at a low temperature, economically, and productively.

The polycrystalline silicon-based thin film is formed in such a state that the pressure of gas during formation of the film is selected and determined from the range of 0.0095 Pa to 64 Pa; the ratio (Md/Ms) of a supply flow rate Md of a diluting gas to a supply flow rate Ms of a film-forming material gas introduced into a deposition chamber is selected and determined from the range of 0 to 1200; the high-frequency power density is selected and determined from the range of 0.0024 W/cm³ to 11 W/cm³; the plasma potentials during formation of the film is maintained to 25 V or lower, and the electron density in the plasma is maintained to 1×10¹⁰ electrons/cm³ or higher; and the combination of those pressures and the like is such a combination that attains the ratio (Ic/Ia=degree of crystallization) of Ic derived from the crystallized silicon component to Ia derived from the amorphous silicon component in the evaluation of the crystallizability of silicon in the film by the laser Raman scattering spectroscopy is 8 or higher.

### TECHNICAL FIELD

The present invention relates to a method for forming a silicon-based thin film, especially a polycrystalline silicon-based thin film by a plasma CVD method.

### BACKGROUND ART

Silicon-based thin films (typically including silicon thin films) have been conventionally employed as materials of TFT (thin film transistor) switches provided in pixels of liquid crystal display devices, or for producing various kinds of integrated circuits, solar cells and other devices.

Silicon thin films are often formed by the plasma CVD method using a silane-based reaction gas. In such a case, most of the thin films are amorphous silicon thin films.

An amorphous silicon thin film can be formed on a deposition target substrate at a relatively low substrate temperature, and can be readily formed over a large area in plasma of a material gas by high-frequency discharge (frequency: 13.56 MHz) using parallel plate electrodes. For this reason, it has been widely used until now for switching devices for pixels of liquid crystal display devices, solar cells and other devices.

However, further improvement in power generation efficiency in solar cells utilizing silicon films, further improvement in response speed and other characteristics of semiconductor devices utilizing silicon films cannot be expected of such amorphous silicon films. Accordingly, use of crystalline silicon thin films (for example, polycrystalline silicon thin films) is contemplated (for example, JP2001-313257A).

For example, known methods of forming the polycrystalline silicon thin film include a method wherein a deposition target substrate is kept at a temperature of 600 to 700° C. or higher, and a CVD method such as a low-pressure plasma CVD method and a thermal CVD method or a PVD method such as a vacuum vapor deposition method and a sputtering vapor deposition method is effected (e.g., refer to JP05-234919A and JP11-054432A), and a method wherein an amorphous silicon thin film is formed at a relatively low temperature by a method among various CVD and PVD methods, and thereafter a heat treatment at about 800° C. is effected or a long-time heat treatment at about 600° C. is effected on the amorphous silicon thin film as a post-treatment (refer to JP05-218368A).

A method in which an amorphous silicon film is crystallized by subjecting the film to a laser annealing process is also known (for example, refer to JP08-124852A, JP2005-197656A, JP2004-253646A).

Meanwhile, in recent years, due to the increased sizes of substrates on which films are to be formed, a technique which can stably form plasma over a large range is drawing attention. That is, in the technique, inductively coupled plasma is produced by applying high-frequency power to a gas from which plasma is to be generated from an antenna of inductive coupling type, and a film is formed in the plasma (for example, JP2004-228354A).

Patent document 1: JP2001-313257A

Patent document 2: JP05-234919A

Patent document 3: JP11-054432A

Patent document 4: JP05-218368A

Patent document 5: JP08-124852A

Patent document 6: JP2005-197656A

Patent document 7: JP2004-253646A

Patent document 8: JP2004-228354A

### DISCLOSURE OF THE INVENTION

### Objects to be Achieved by the Invention

In one or some of these methods, however, the deposition target substrate is to be exposed to a high temperature, in which case it is necessary to employ, as the substrate for film deposition, a substrate which is resistant to a high temperature and thus is expensive, and it is difficult to form a crystalline silicon thin film on an inexpensive glass substrate having a low melting point (having a heat-resistant temperature not exceeding 500° C.). Therefore, the production cost of the crystalline silicon thin films such as polycrystalline silicon thin films disadvantageously increases.

When the laser annealing method is employed, although a crystalline silicon thin film can be obtained at a low temperature, a laser irradiation step is necessary and a laser beam having very high energy density needs to be irradiated. For these and other reasons, the production cost of the crystalline silicon thin film is also high in this case.

Furthermore, it cannot be yet said that the method for forming silicon thin films by inductively coupled plasma, which is thought to be suitable for forming films on substrates having large areas, has been established.

A first object of the present invention is to provide a method for forming a silicon-based thin film by a plasma CVD method which can form a polycrystalline silicon-based thin film having high degree of crystallization relatively at a low temperature, economically and productively.

A second object of the present invention is to provide a method for forming a silicon-based thin film by a plasma CVD method which can achieve the above-mentioned first object and form a high-quality polycrystalline silicon-based thin film with few defects.

### Means for Achieving the Objects

According to the research conducted by the inventors of the present invention, when a polycrystalline silicon-based thin film is used for producing a TFT (thin film transistor) switch, or as a semiconductor film for producing various kinds of integrated circuits, solar cells and the like, to improve the performance of these switches and the like, the film preferably meets the following condition: The ratio (Ic/Ia=the degree of crystallization) of Raman scattering peak intensity Ic derived from a crystallized silicon component to Raman scattering peak intensity Ia derived from an amorphous silicon component in the crystallizability evaluation of silicon in the film determined by the laser Raman scattering spectroscopy is high. More specifically, the degree of crystallization is preferably 8 or higher, and more preferably 10 or higher. When the degree of crystallization (Ic/Ia)=10, the degree of crystallization of the silicon component is almost 100%.

The inventors of the present invention conducted extensive research to form such a polycrystalline silicon-based thin film having a degree of crystallization of 8 or higher, and found the followings:

(1) The plasma CVD method can be utilized for forming the film. More specifically, the plasma CVD method in which a film-forming material gas containing silicon atoms or the film-forming material gas containing silicon atoms and a diluting gas for diluting the film-forming material gas are introduced into a deposition chamber, plasma is generated from the introduced gas(es) by high-frequency excitation, and a silicon-based thin film is formed in the plasma on a deposition target substrate disposed in the deposition chamber, can be utilized. Films can be formed productively at a relatively low temperature by the plasma CVD method, and this method also allows, for example, formation of films on inexpensive low melting point glass substrates (typically including non-alkali glass substrates) having a heat-resistant temperature of 500° C. or lower, and films can be formed proportionally economically;
(2) The internal pressure of the deposition chamber during formation of the film by the plasma CVD method is preferably selected and determined from the range of 0.0095 Pa to 64 Pa;
(3) The ratio (Md/Ms) of a supply flow rate Md [sccm] of the diluting gas to a supply flow rate Ms [sccm] of the film-forming material gas introduced into the deposition chamber during formation of the film is preferably selected and determined from the range of 0 to 1200 (when Md/Ms=0, the diluting gas is not used.);
(4) The high-frequency power density during formation of the film is preferably selected and determined from the range of 0.0024 W/cm³ to 11 W/cm³;
(5) It is preferable that the plasma potential during formation of the film is maintained to 25 V or lower, and it is preferable to maintain the electron density in plasma during formation of the film to 1×10¹⁰ electrons/cm³or higher; and
(6) A polycrystalline silicon-based thin film having a degree of crystallization of 8 or higher can be formed when the above-stated conditions are met.

The reason why it is preferable to select and determine the pressure inside the deposition chamber during formation of the film from the range of 0.0095 Pa to 64 Pa is as follows: if the pressure is lower than 0.0095 Pa, plasma become unstable and the film formation rate is lowered, and igniting and maintaining plasma are disabled in extreme cases; when the pressure is higher than 64 Pa, the crystallizability of silicon is lowered and it is difficult to form a polycrystalline silicon-based thin film having a degree of crystallization (Ic/Ia)≧8.

The reason why it is preferable to set the ratio (Md/Ms) of the supply flow rate Md [sccm] of the diluting gas to the supply flow rate Ms [sccm] of the film-forming material gas during formation of the film within the range of 0 to 1200 is as follows: when the ratio (Md/Ms) is higher than 1200, the crystallizability of silicon is lowered, and it is difficult to form a polycrystalline silicon-based thin film having a degree of crystallization (Ic/Ia)≧8, and the film formation rate is lowered.

The reason why it is preferable to select and determine the high-frequency power density during formation of the film from the range of 0.0024 W/cm³ to 11 W/cm³ is as follows: When the density is lower than 0.0024 W/cm³, the plasma becomes unstable and the film formation rate is lowered, and igniting and maintaining plasma becomes difficult in extreme cases; When the density is higher than 11 W/cm³, the crystallizability of silicon is lowered to make formation of a polycrystalline silicon-based thin film having a degree of crystallization (Ic/Ia)≧8 difficult, and the film formation rate is lowered.

The term “high-frequency power density [W/cm³]” used herein means a value obtained by dividing an input high-frequency power [W] by the volume [cm³] of a plasma producing space (normally, deposition chamber).

The reason why it is preferable to maintain the plasma potential during formation of the film to 25 V or lower is as follows: when the potential is higher than 25 V, crystallization of silicon is likely to be inhibited, and it is difficult to form a polycrystalline silicon-based thin film having a degree of crystallization (Ic/Ia)≧8.

However, when the potential is too low, maintaining plasma becomes difficult, and therefore the potential may be, but not limited to, 10 V or higher in general.

The reason why it is preferable to maintain the electron density in the plasma during formation of the film to 1×10¹⁰ electrons/cm³ or higher is as follows: when the electron density is lower than 1×10¹⁰ electrons/cm³, ion density which contributes to film formation is also lowered; the degree of crystallization of silicon is lowered; and the film formation rate is lowered, whereby it becomes difficult to form a polycrystalline silicon-based thin film having a degree of crystallization (Ic/Ia)≧8.

However, if the electron density is too high, the film and deposition target substrate becomes susceptible to damages caused by incident ions and like charged particles. Therefore, considering the attainment of the degree of crystallization (Ic/Ia)≧8, the electron density may be, but not limited to, about 1.0×10¹² electrons/cm³or lower in general.

An increase and decrease in the plasma potential affects an increase or decrease in the electron density in the plasma. There are the tendencies that the higher the plasma potential, the higher the electron density, and that the lower the plasma potential, the lower the electron density. Therefore, these elements need to be determined by considering the attainment of a degree of crystallization (Ic/Ia)≧8.

Such plasma potential and the electron density of plasma can be adjusted by controlling at least one of the magnitude of applied high-frequency power (in other word, high-frequency power density), the frequency of the high-frequency wave, deposition pressure and others.

On the basis of the findings described above, to achieve the first object, the present invention provides a method for forming a silicon-based thin film by a plasma CVD, in which, of a film-forming material gas containing silicon atoms and a diluting gas, at least the film-forming material gas is introduced into a deposition chamber; plasma is generated from the introduced gas by high-frequency excitation; and a silicon-based thin film is formed in the plasma on a deposition target substrate disposed in the deposition chamber, where pressure inside the deposition chamber during formation of the film is selected and determined from a range of 0.0095 Pa to 64 Pa; ratio (Md/Ms) of supply flow rate Md [sccm] of the diluting gas to supply flow rate Ms [sccm] of the film-forming material gas introduced into the deposition chamber during formation of the film is selected and determined from a range of 0 to 1200; high-frequency power density during formation of the film is selected and determined from a range of 0.0024 W/cm³ to 11 W/cm³; plasma potential during formation of the film is maintained at 25 V or lower and electron density in the plasma during formation of the film is maintained at 1×10¹⁰ electrons/cm³ or higher; and the film is formed while combination of the pressure inside the deposition chamber during formation of the film selected and determined, the supply flow rate ratio (Md/Ms) of the film-forming material gas to the diluting gas, the high-frequency power density and the plasma potential to be maintained, and the electron density in the plasma is such a combination that allows providing a polycrystalline silicon-based thin film in which ratio (Ic/Ia=degree of crystallization) of Raman scattering peak intensity Ic derived from a crystallized silicon component to Raman scattering peak intensity Ia derived from an amorphous silicon component in crystallizability evaluation of silicon in the film determined by a laser Raman scattering spectroscopy is 8 or higher.

In the method for forming a silicon-based thin film according to the present invention, high-frequency power input for producing plasma from the gas is efficiently utilized to form high-density plasma in the deposition chamber. Moreover, to stably form plasma over a large range so that a film as homogeneous as possible is formed, producing plasma from the gas introduced into the deposition chamber by high-frequency excitation may be conducted by applying high-frequency power to the introduced gas from an antenna of inductive coupling type (an inductively coupled antenna) placed in the deposition chamber.

When the antenna of inductive coupling type is placed in the deposition chamber as stated above, it is preferable that the antenna is covered with an electrical insulating material. By covering the antenna with an electrical insulating material, it is suppressed that the antenna is sputtered by charged particles from plasma due to self-bias, and that sputtered particles derived from the antenna get into the film to be formed.

Examples of such insulating materials include quartz glass, and materials produced by the anodization process of the antenna.

In any case, examples of polycrystalline silicon-based thin films which can be formed by the method for forming a film according to the present invention include polycrystalline silicon thin films comprising silicon. Other examples include polycrystalline silicon-based thin films containing germanium (for example, containing 10 atomic % or less of germanium) and polycrystalline silicon-based thin films containing carbon (for example, containing 10 atomic % or less of carbon).

In any case, Raman scattering intensity at a wave number of 480⁻¹ cm can be employed as the Raman scattering peak intensity Ia derived from the amorphous silicon component. Moreover, Raman scattering peak intensity at a wave number of 520⁻¹ cm or therearound can be employed as the Raman scattering peak intensity Ic derived from the crystallized silicon component.

When a polycrystalline silicon thin film is formed, examples of the material gases containing silicon atoms include monosilane (SiH₄) gas, disilane (Si₂H₆) gas and like silane-based gases. When a diluting gas is used, examples of the diluting gas include hydrogen gas.

When a polycrystalline silicon-based thin film containing germanium is formed, a gas containing silicon atoms and also containing germanium atoms may be employed as the film-forming material gas containing silicon atoms. Specific examples of such a film-forming material gas include a gas produced by mixing a gas containing germanium [for example, monogermane (GeH₄) gas, germanium tetrafluoride (GeF₄) gas] with a silane-based gas such as monosilane (SiH₄) gas, disilane (Si₂H₆) gas and like gases.

When a diluting gas is used, for example, hydrogen gas can be used as the diluting gas also in this case.

When a polycrystalline silicon-based thin film containing carbon is formed, a gas containing silicon atoms and also containing carbon atoms may be employed as the film-forming material gas containing silicon atoms. Specific examples of such a film-forming material gas include a gas produced by mixing a gas containing carbon [for example, methane (CH₄) gas, carbon tetrafluoride (CF₄) gas] with a silane-based gas such as monosilane (SiH₄) gas, disilane (Si₂H₆) gas and like gases.

When a diluting gas is used, for example, a hydrogen gas can be used as the diluting gas also in this case.

It is desirable that the surface of the polycrystalline silicon-based thin film is subjected to a terminating treatment with oxygen, nitrogen or other elements. The term “terminating treatment” used herein refers to a treatment wherein oxygen and/or nitrogen is bonded to the surface of the polycrystalline silicon-based thin film to give a (Si—O) bond, a (Si—N) bond, a (Si—O—N) bond or the like.

The oxygen bond or nitrogen bond formed by such terminating treatment can function so as to compensate a defect, e.g., uncombined dangling bond, on the surface of the terminally untreated crystalline silicon thin film and can give a high-quality state in which the defect is substantially suppressed as a whole. When employed as electronic device materials, the crystalline silicon thin film so terminally treated can achieve improvements in the properties required of the electronic devices. For example, when used as a TFT material, the terminally treated crystalline silicon thin film can improve the electron mobility in the TFT and can reduce OFF-current.

Moreover, the crystalline silicon thin film can improve the TFT in reliability, such as stability of the voltage-current characteristics even in the use of the TFT for a long period of time.

To achieve the second object, the present invention provides

a method for forming a silicon-based thin film according to the present invention, in which after the polycrystalline silicon-based thin film is formed, the surface of the polycrystalline silicon-based thin film is subjected to a terminating treatment in plasma for terminating treatment produced by applying high-frequency power to at least one gas for terminating treatment selected from an oxygen-containing gas and a nitrogen-containing gas.

Such a terminating treatment may be conducted in the following manner if there is no adverse effect: after the polycrystalline silicon-based thin film is formed, a gas for terminating treatment is introduced into the same deposition chamber; high-frequency power is applied to the gas to generate plasma for terminating treatment; and the surface of the polycrystalline silicon-based thin film is subjected to a terminating treatment in the plasma.

A terminally treating chamber which is independent of the deposition chamber may be prepared, and a terminating treatment step may be carried out in the terminally treating chamber.

Moreover, after the polycrystalline silicon-based thin film is formed in the deposition chamber, a substrate on which the polycrystalline silicon-based thin film is formed may be loaded into the terminally treating chamber which is in communication with the deposition chamber (directly or indirectly, e.g., via a transference chamber having a goods transferring robot), and the terminating treatment may be carried out in the terminally treating chamber.

In the terminating treatment in such a terminally treating chamber, a high-frequency discharge electrode which applies high-frequency power to the gas for terminating treatment may be also an antenna which produce inductively coupled plasma as described above.

As mentioned above, an oxygen-containing gas or (and) a nitrogen-containing gas is used as the gas for terminating treatment. Examples of the oxygen-containing gas include oxygen gas and nitrogen oxide (N₂O) gas, and examples of the nitrogen-containing gas include nitrogen gas and ammonia (NH₃) gas.

### EFFECT OF THE INVENTION

As described above, according to the present invention, a method for forming a silicon-based thin film by a plasma CVD method which can form a polycrystalline silicon-based thin film having a high degree of crystallization relatively at a low temperature, economically and productively can be provided.

According to the present invention, a method for forming a silicon-based thin film by a plasma CVD method, which can achieve the above-mentioned advantages, and also can form a high-quality polycrystalline silicon-based thin film with few defects, can be provided.

### BRIEF DESCRIPTION OF DRAWINGS

FIG. 1 shows an example of a thin film formation apparatus which can be used in a method for forming a polycrystalline silicon-based thin film of the present invention.

FIG. 2 shows a relationship between degree of crystallization (Ic/Ia) of the formed film and pressure inside the deposition chamber during formation of the film.

FIG. 3 shows a relationship between degree of crystallization (Ic/Ia) of the formed film and gas supply flow rate ratio during formation of the film.

FIG. 4 shows a relationship between degree of crystallization (Ic/Ia) of the formed film and high-frequency power density during formation of the film.

FIG. 5 shows a relationship between degree of crystallization (Ic/Ia) of the formed film and plasma potential during formation of the film.

### DESCRIPTION OF THE SYMBOLS

1 Deposition chamber
11 Top wall of deposition chamber 1
111 Electrical insulation member provided on top wall 11
2 Substrate holder
21 Heater
3 Antenna of inductive coupling type
31, 32 Ends of antenna 3
4 High-frequency power source
41 Matching box
5 Exhaust pump
51 Conductance valve
6 Film-forming material gas supply unit
7 Diluting gas supply unit
8 Gas for terminating treatment supply unit
10 Plasma diagnosis apparatus
10a Langmuir probe
10b Plasma diagnosing unit
100 Pressure gage

### BEST MODE FOR IMPLEMENTING THE INVENTION

Embodiments of the present invention will be described below with reference to drawings.

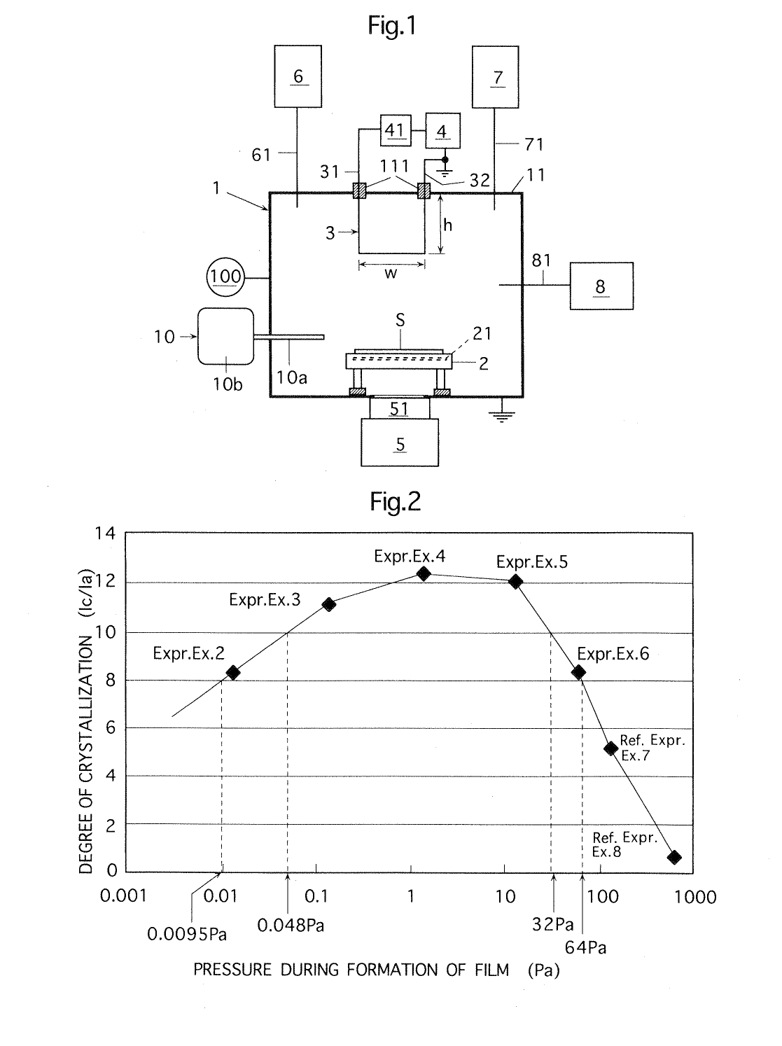

FIG. 1 schematically shows the constitution of an example of a thin film formation apparatus which can be used for carrying out the method for forming a silicon-based thin film (polycrystalline silicon-based thin film) according to the present invention.

The thin film formation apparatus of FIG. 1 comprises a deposition chamber 1. A holder 2 which retains a deposition target substrate S is placed in a lower part of the deposition chamber 1. The holder 2 has integrated therein a heater 21 which can heat the substrate S retained by the holder.

An antenna 3 of inductive coupling type is disposed in a region opposing the holder 2 in an upper part of the deposition chamber 1. The antenna 3 has the shape of an inverted gate, and its both ends 31, 32 are extending to the outside of the deposition chamber 1 through an insulation member 111 provided on the top wall 11 of the deposition chamber. The width of the antenna 3 in the deposition chamber 1 is W, and the length of the same is h.

An output-variable high-frequency power source 4 is connected to the end 31 of the antenna projecting to the outside of the deposition chamber via a matching box 41. The other end 32 of the antenna is grounded.

An exhaust pump 5 is connected to the deposition chamber 1 via an exhaust amount adjustment valve (conductance valve in this example) 51. Furthermore, a film-forming material gas supply unit 6 is connected to the chamber via a gas inlet pipe 61, and a diluting gas supply unit 7 is connected to the chamber via a gas inlet pipe 71. Furthermore, a gas for terminating treatment supply unit 8 is connected to the chamber via a gas inlet pipe 81. Each of the gas supply units 6, 7 and 8 includes a massflow controller for adjusting the amount of the gas supplied into the deposition chamber, a gas source and other components.

The holder 2 is set at a ground potential via the deposition chamber 1.

A plasma diagnosis apparatus 10 using a Langmuir probe and a pressure gage 100 are provided for the deposition chamber 1. The plasma diagnosis apparatus 10 can determine a plasma potential and an electron density in the plasma based on a Langmuir probe 10a inserted into the deposition chamber 1 and the plasma information obtained by the probe. The pressure inside the deposition chamber can be measured by the pressure gage 100.

According to the thin film formation apparatus described above, a polycrystalline silicon-based thin film can be formed, for example, in the following manner, and further a terminating treatment can be conducted on the film.

First, the deposition target substrate S is retained on the holder 2 in the deposition chamber 1; the substrate is heated, if necessary, by the heater 21; and the deposition chamber is evacuated until the pressure inside the deposition chamber is lower than the pressure during formation of the film by operating the exhaust pump 5. Second, a film-forming material gas containing silicon atoms is introduced into the deposition chamber 1 from the film-forming material gas supply unit 6, or a film-forming material gas containing silicon atoms is introduced from the gas supply unit 6 and at the same time a diluting gas is introduced from the diluting gas supply unit 7; high-frequency power is applied to the antenna 3 from the variable high-frequency power source 4 via the matching box 41 while the pressure inside the deposition chamber is adjusted to the film formation pressure by the conductance valve 51.

Accordingly, the high-frequency power is applied to the gas in the deposition chamber from the antenna, whereby the gas is excited at a high frequency to generate inductively coupled plasma, and a silicon-based thin film is formed on the substrate S in the plasma.

In this film formation, the film is formed in the following states: the pressure inside the deposition chamber during formation of the film is selected and determined from the range of 0.0095 Pa to 64 Pa; the ratio (Md/Ms) of the supply flow rate Md [sccm] of the diluting gas to the supply flow rate Ms [sccm] of the film-forming material gas introduced into the deposition chamber 1 is selected and determined from the range of 0 to 1200; the high-frequency power density is selected and determined from the range of 0.0024 W/cm³ to 11 W/cm³; and further the plasma potential during formation of the film is maintained at 25 V or lower; and the electron density in the plasma during formation of the film is maintained within a range of 1×10¹⁰ electrons/cm³ or higher.

Furthermore, the film is formed in such a state that the combination of the pressure inside the deposition chamber during formation of the film thus selected and determined, the supply flow rate ratio (Md/Ms) of the film-forming material gas to the diluting gas, the high-frequency power density, the plasma potential to be maintained and the electron density in plasma is such a combination that allows formation of a polycrystalline silicon-based thin film having a ratio (Ic/Ia=degree of crystallization) of Raman scattering peak intensity Ic derived from a crystallized silicon component to Raman scattering peak intensity Ia derived from an amorphous silicon component in the crystallizability evaluation of silicon in the film determined by the laser Raman scattering spectroscopy of 8 or higher, and more preferably, 10 or higher. Thus, a polycrystalline silicon-based thin film is formed on the substrate S.

Although the pressure in the deposition chamber is also affected by the amount of the gas supplied, adjustment of the pressure in the deposition chamber can be easily performed by adjusting the amount of the gas supplied by the conductance valve 51 after the amount of the gas supplied is made constant. The pressure inside the deposition chamber can be detected by the pressure gage 100. The adjustment of the amounts of the gases supplied into the deposition chamber and the adjustment of the supply flow rate ratio (Md/Ms) can be performed by the massflow controller(s).

The adjustment of the density of high-frequency power can be performed by adjusting the output of the high-frequency power source 4.

The plasma potential and electron density can be detected by the plasma diagnosis apparatus 10.

In this film formation, the pressure inside the deposition chamber during formation of the film, the ratio of the amounts of the gases supplied (Md/Ms), the density of high-frequency power, the plasma potential and the electron density which achieve a degree of crystallization (Ic/Ia) of 8 or higher, and more preferably, 10 or higher are determined from the above-mentioned ranges, respectively. Examples of the methods for determining such ranges include selecting and determining the pressure inside the deposition chamber, the gas supply flow rate ratio (Md/Ms) and the high-frequency power density to be those of when it is confirmed that the plasma potential and the electron density are in the range of 25 V or lower and 1×10¹⁰ electrons/cm³ or higher, respectively, by the plasma diagnosis apparatus 10, and to fall within the above-mentioned ranges, respectively.

Alternatively, the combination of the pressure inside the deposition chamber during formation of the film, the gas supply flow rate ratio (Md/Ms), the density of high-frequency power, the plasma potential and the electron density when a degree of crystallization (Ic/Ia) of 8 or higher, and more preferably, 10 or higher, is achieved may be determined in advance by experimenting or the like, and the pressure inside the deposition chamber, the gas supply flow rate ratio (Md/Ms), the density of high-frequency power, the plasma potential and the electron density may be selected and determined from the groups of those combinations.

After a polycrystalline silicon-based thin film comprising silicon as a main ingredient and having a degree of crystallization of 8 or higher is formed in this manner, the film may be subjected to a terminating treatment.

For example, introduction of gas into the chamber 1 from the gas supply unit 6 (or 6 and 7) and application of electric power from the power supply 4 to the antenna 3 are stopped, while the operation of the exhaust pump 5 is continued to discharge the gas from the inside of the deposition chamber 1 as much as possible.

Thereafter, while the substrate temperature is maintained, for example, within the range of 250° C. to 400° C., a terminating treatment gas, for example, oxygen gas or nitrogen gas is introduced into the deposition chamber 1 from the terminating treatment gas supply unit 8 at a flow rate within the range of 50 sccm to 500 sccm; the pressure inside the deposition chamber is set to a pressure for terminating treatment (pressure ranging from about 0.1 Pa to 10 Pa); high-frequency power for terminating treatment (for example, electric power of about 13.56 MHz, about 0.5 kW to 3 kW) is further applied to the antenna 3 from the high-frequency power source 4 via the matching box 41 to produce plasma from the gas for terminating treatment; and the surface of the polycrystalline silicon-based thin film on the substrate S is subjected to a terminating treatment for a predetermined treating time (for example, about 0.5 minutes to 10 minutes) in the plasma, whereby the polycrystalline silicon-based thin film is improved in quality.

When the polycrystalline silicon-based thin film which has been subjected to a terminating treatment with oxygen or nitrogen in this manner is used as a semiconductor film, for example, for TFTs, the electron mobility as TFT electrical characteristics is further improved and the OFF-current is lowered than in the case where no terminating treatment is conducted.

The terminating treatment with the nitrogen-containing gas may be carried out before or after the terminating treatment by the oxygen-containing gas.

Subsequently, experimental examples in which a polycrystalline silicon thin film was formed as an example of the polycrystalline silicon-based thin film will be described. Prior to the experiment, the antennas shown below were prepared as the antenna 3 of inductive coupling type, and one of these antennas was used in each experiment.

| | Antennas: | | | | | |
|---|---|---|---|---|---|---|
| | A | B | C | D | E | F |
| Width w: | 140 mm | 120 mm | 50 mm | 50 mm | 50 mm | 50 mm |
| Length h: | 110 mm | 70 mm | 80 mm | 65 mm | 55 mm | 50 mm |

The evaluation of the degree of crystallization of silicon of the formed films was performed by the laser Raman scattering spectroscopy using a He—Ne laser (wavelength: 632.8 nm), and was carried out using the ratio (Ic/Ia=degree of crystallization) of the Raman scattering peak intensity Ic derived from the crystallized silicon component to the Raman scattering peak intensity Ia derived from the amorphous silicon component in the evaluation of the crystallizability of silicon in the films.

Moreover, the Raman scattering intensity at a wave number of 480⁻¹ cm was employed herein as the Raman scattering peak intensity Ia derived from the amorphous silicon component, and the Raman scattering peak intensity at a wave number of 520⁻¹ cm or therearound was employed as the Raman scattering peak intensity Ic derived from the crystallized silicon component.

In any of the experiments, in forming the film, a non-alkali glass substrate was retained on the holder 2 as the substrate S; the substrate was heated to 400° C. by the heater 21; monosilane (SiH₄) gas was used as a film-forming material gas; hydrogen gas (H₂) was used as a diluting gas, when used; the deposition chamber 1 was evacuated at first by the exhaust pump 5 to adjust the internal pressure of chamber in the order of 10⁻⁵ Pa; and then a silicon thin film was formed on the non-alkali glass substrate by introducing the gases into the chamber, applying high-frequency power at a frequency of 13.56 MHz to the antenna 3 and igniting plasma according to the specification of each experiment,

Reference Experimental Example 1, Experimental Examples 2 to 6 and Reference Experimental Examples 7 to 8, which were prepared under the conditions described below, are collectively shown in Table 1 below: the antenna used was antenna C; the supply flow rate (Md) of hydrogen gas was constantly 20 sccm; the supply flow rate (Ms) of monosilane gas was constantly 2 sccm; the supply flow rate ratio (Md/Ms) thus had a constant value of 10; the density of the high-frequency power supplied was constantly 0.01 W/cm³; and the pressures inside the deposition chamber were varied.

The relationships between the measurement results of the degree of crystallization (Ic/Ia) of the silicon thin films formed and the pressures inside the deposition chamber during formation of the films are shown in FIG. 2.

TABLE 1

| | Ref. | | | | | | Ref. | Ref. |
|---|---|---|---|---|---|---|---|---|
| | Expr. Ex. 1 | Expr. Ex. 2 | Expr. Ex. 3 | Expr. Ex. 4 | Expr. Ex. 5 | Expr. Ex. 6 | Expr. Ex. 7 | Expr. Ex. 8 |
| Pressure during | 0.0013 Pa | 0.013 Pa | 0.13 Pa | 1.3 Pa | 13 Pa | 60 Pa | 130 Pa | 650 Pa |
| film formation | | | | | | | | |
| Flow rate of | H₂ 20 sccm | H₂ 20 sccm | H₂ 20 sccm | H₂ 20 sccm | H₂ 20 sccm | H₂ 20 sccm | H₂ 20 sccm | H₂ 20 sccm |
| diluting gas | | | | | | | | |
| Flow rate of | SiH₄ 2 sccm, | SiH₄ 2 sccm | SiH₄ 2 sccm | SiH₄ 2 sccm | SiH₄ 2 sccm | SiH₄ 2 sccm | SiH₄ 2 sccm | SiH₄ 2 sccm |
| material gas | | | | | | | | |
| Ratio of flow | 10 | 10 | 10 | 10 | 10 | 10 | 10 | 10 |
| rate of diluting | | | | | | | | |
| gas to flow | | | | | | | | |
| rate of material | | | | | | | | |
| gas | | | | | | | | |
| High-frequency | 0.01 W/cm³ | 0.01 W/cm³ | 0.01 W/cm³ | 0.01 W/cm³ | 0.01 W/cm³ | 0.01 W/cm³ | 0.01 W/cm³ | 0.01 W/cm³ |
| power density | | | | | | | | |
| Plasma | Immeasurable | 27 V | 22 V | 19 V | 15 V | 14 V | 13 V | 12 V |
| potential | | | | | | | | |
| Electron | Immeasurable | 7.1 × 10¹⁰/cm³ | 5.7 × 10¹⁰/cm³ | 4.4 × 10¹⁰/cm³ | 3.0 × 10¹⁰/cm³ | 2.6 × 10¹⁰/cm³ | 1.9 × 10¹⁰/cm³ | 1.2 × 10¹⁰/cm³ |
| density | | | | | | | | |
| Type of | Antenna C | Antenna C | Antenna C | Antenna C | AntennaC | AntennaC | Antenna C | antenna C |
| antenna | | | | | | | | |

In Experimental Examples 2 to 6, silicon thin films which have been crystallized to a degree of crystallization of 8 or higher were formed.

However, plasma was not ignited in Reference Experimental Example 1, and no silicon thin film could be formed. This is because the deposition pressure was too low so that gas molecules sufficient for igniting and maintaining plasma were not present in the chamber 1.

Ic/Ia was gradually lowered in Experimental Example 6 and Reference Experimental Examples 7, 8, and Ic/Ia was greatly lowered in Reference Experimental Examples 7, 8. This is because generation of atom-like hydrogen radicals which play a significant roll in the crystallization of silicon was inhibited by increased deposition pressure.

In Experimental Examples 3, 2, Ic/Ia exhibits a decreasing tendency despite of the lowered pressure. This is because although generation of the atom-like hydrogen radicals is promoted, there is a tendency that chemical etching-like damaging action which proceeds simultaneously with and in parallel to crystallization promoting action exceeds the crystallization promoting action. It is also because the plasma potential is increased simultaneously, the damaging action of the plasma is also increased.

It can be seen from FIG. 2 that if the pressures inside the deposition chamber during formation of the films are set within the range of about 0.0095 Pa to 64 Pa, Ic/Ia≧8 can be attained. Moreover, if the pressures inside the deposition chamber during formation of the films are set within the range of about 0.048 Pa to 32 Pa, Ic/Ia≧10 can be attained, which is more preferable.

Subsequently, Experimental Examples 9 to 13 and Reference Experimental Example 14 are collectively shown in Table 2 below. In these Examples, the antenna used was antenna C; the pressure during formation of the film was constantly set to 1.3 Pa; the density of the high-frequency power supplied was constantly set to 0.01 W/cm³; and the gas supply flow rate ratio (Md/Ms) was varied.

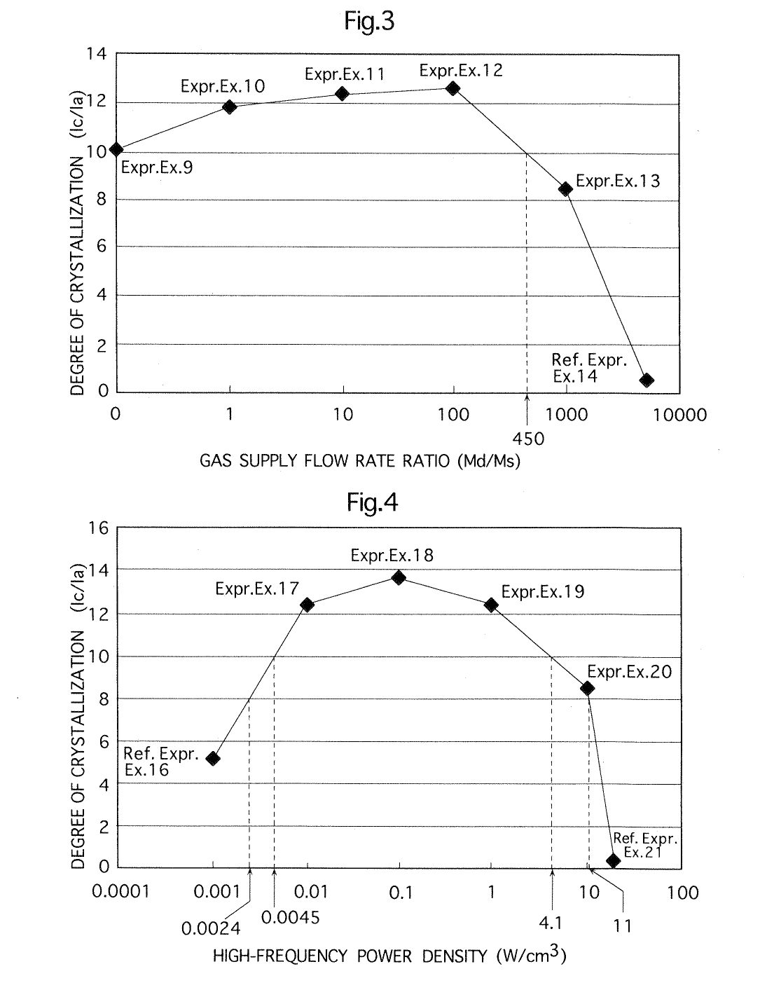

The relationships between the measurement results of the degree of crystallization (Ic/Ia) of the silicon thin films formed and the ratios of the gas supply flow rates (Md/Ms) during formation of the films are shown in FIG. 3.

TABLE 2

| | | | Expr. Ex. | | | |
|---|---|---|---|---|---|---|
| | | | 11 | | | |
| | | Expr. Ex. | (=Expr. | Expr. Ex. | Expr. Ex. | Ref. Expr. |
| | Expr. Ex. 9 | 10 | Ex. 4) | 12 | 13 | Ex. 14 |
| Pressure during film | 1.3 Pa | 1.3 Pa | 1.3 Pa | 1.3 Pa | 1.3 Pa | 1.3 Pa |
| formation | | | | | | |
| Flow rate of diluting | None | H₂ | H₂ | H₂ | H₂ 2000 sccm | H₂ 10000 sccm |
| gas | | 1 sccm | 20 sccm | 200 sccm | | |
| Flow rate of material | SiH₄ | SiH₄ | SiH₄ | SiH₄ | SiH₄ | SiH₄ |
| gas | 2 sccm | 2 sccm | 2 sccm | 2 sccm | 2 sccm | 2 sccm |
| Ratio of flow rate of | 0 (no | 1 | 10 | 100 | 1000 | 5000 |
| diluting gas to ratio | diluting | | | | | |
| of flow rate of | gas) | | | | | |
| material gas | | | | | | |
| High-frequency | 0.01 W/cm³ | 0.01 W/cm³ | 0.01 W/cm³ | 0.01 W/cm³ | 0.01 W/cm³ | 0.01 W/cm³ |
| power density | | | | | | |
| Plasma potential | 18 V | 18 V | 19 V | 20 V | 19 V | 19 V |
| Electron density | 4.4 × 10¹⁰/cm³ | 4.6 × 10¹⁰/cm³ | 4.4 × 10¹⁰/cm³ | 4.4 × 10¹⁰/cm³ | 4.5 × 10¹⁰/cm³ | 4.3 × 10¹⁰/cm³ |
| Type of antenna | Antenna C | Antenna C | Antenna C | Antenna C | Antenna C | Antenna C |

In Experimental Examples 9 to 13, silicon thin films which have been crystallized to a degree of crystallization of 8 or higher were formed.

The reason why Ic/Ia increases in the order of Experimental Examples 9, 10, 11 and 12 is that the higher the hydrogen gas supply flow rate, the more the amount of the atom-like hydrogen radicals, and the more the crystallization is promoted. The reason why Ic/Ia decreases in the order of Experimental Example 13 and Reference Experimental Example 14 and significantly decreases in Reference Experimental Example 14 is because although the atom-like hydrogen radicals increases, there is a tendency that chemical etching-like damaging action which proceeds simultaneously with and parallel to crystallization promoting action exceeds the crystallization promoting action.

The reason why Experimental Example 9 which employs no diluting gas has high degree of crystallization is because the monosilane gas was decomposed and resultant hydrogen (H) was supplied to form atom-like hydrogen radicals.

It can be seen from FIG. 3 that if the gas supply flow rate ratio (Md/Ms) is set within the range of about 0 to 1200, Ic/Ia≧8 can be attained. Moreover, if the gas supply flow rate ratio (Md/Ms) is set within the range of about 0 to 450, Ic/Ia≧10 can be attained, which is more preferable.

Subsequently, Reference Experimental Examples 15 to 16, Experimental Examples 17 to 20 and Reference Experimental Example 21 are collectively shown in Table 3 below. In these Examples, the antenna used was antenna C: the pressure during formation of the film was constantly set to 1.3 Pa; the amount of the hydrogen gas introduced (Md) was constantly set to 20 sccm; the amount of the monosilane gas introduced (Ms) was constantly set to 2 sccm; therefore the supply flow rate ratio (Md/Ms) constantly had a value of 10; and the density of the high-frequency power supplied was varied.

The relationships between the measurement results of the degree of crystallization (Ic/Ia) of the silicon thin films formed and the high-frequency power densities during formation of the films are shown in FIG. 4.

TABLE 3

| | | | Expr. | | | | |
|---|---|---|---|---|---|---|---|
| | Ref. | Ref. | Ex. 17 | | | | Ref. |
| | Expr. | Expr. | (=Expr. | Expr. | Expr. | Expr. | Expr. |
| | Ex. 15 | Ex. 16 | Ex. 4) | Ex. 18 | Ex. 19 | Ex. 20 | Ex. 21 |
| Pressure | 1.3 Pa | 1.3 Pa | 1.3 Pa | 1.3 Pa | 1.3 Pa | 1.3 Pa | 1.3 Pa |
| during film | | | | | | | |
| formation | | | | | | | |
| Flow rate of | H₂ | H₂ | H₂ | H₂ | H₂ | H₂ | H₂ |
| diluting gas | 20 sccm | 20 sccm | 20 sccm | 20 sccm | 20 sccm | 20 sccm | 20 sccm |
| Flow rate of | SiH₄ | SiH₄ | SiH₄ | SiH₄ | SiH₄ | SiH₄ | SiH₄ |
| material gas | 2 sccm | 2 sccm | 2 sccm | 2 sccm | 2 sccm | 2 sccm | 2 sccm |
| Ratio of flow | 10 | 10 | 10 | 10 | 10 | 10 | 10 |
| rate of | | | | | | | |
| diluting gas | | | | | | | |
| to flow rate | | | | | | | |
| of material | | | | | | | |
| gas | | | | | | | |
| High-frequency | 0.0001 W/cm³ | 0.001 W/cm³ | 0.01 W/cm³ | 0.1 W/cm³ | 1 W/cm³ | 10 W/cm³ | 20 W/cm³ |
| power | | | | | | | |
| density | | | | | | | |
| Plasma | Inmesurable | 22 V | 19 V | 18 V | 17 V | 17 V | 15 V |
| potential | | | | | | | |
| Electron | Inmesurable | 3.2 × 10¹⁰/cm³ | 4.4 × 10¹⁰/cm³ | 6.0 × 10¹⁰/cm³ | 7.3 × 10¹⁰/cm³ | 8.5 × 10¹⁰/cm³ | 9.7 × 10¹⁰/cm³ |
| density | | | | | | | |
| Type of | Antenna C | Antenna C | Antenna C | Antenna C | Antenna C | Antenna C | Antenna C |
| antenna | | | | | | | |

In Experimental Examples 17 to 20, silicon thin films which have been crystallized to a degree of crystallization of 8 or higher were formed.

In Reference Experimental Example 15, plasma was not ignited, and no silicon thin film could be formed. This is because the high-frequency power density was too low, and it was therefore impossible to produce plasma from the gas.

The reason why Ic/Ia increases in the order of Reference Experimental Example 16, Experimental Examples 17, 18 is because the higher the high-frequency power density, the more the decomposition of the gas proceeds (conversion into plasma), and generation of the atom-like hydrogen radicals is promoted.

Ic/Ia decreases in the order of Experimental Examples 19, 20, and Reference Experimental Example 21, and Ic/Ia significantly drops in Reference Experimental Example 21. This is because although the atom-like hydrogen radicals increase, there is a tendency that chemical etching-like damaging action which proceeds simultaneously with and parallel to the crystallization promoting action exceeds the crystallization promoting action.

It can be seen from FIG. 4 that if the high-frequency power density during formation of the film is set within the range of about 0.0024 W/cm³ to 11 W/cm³, Ic/Ia≧8 can be attained. Moreover, if the high-frequency power density during formation of the film is set within the range of about 0.0045 W/cm³ to 4.1 W/cm³, Ic/Ia≧10 can be attained, which is more preferable.

Subsequently, Reference Experimental Examples 22 to 23, Experimental Examples 24 to 25 and Reference Experimental Examples 26 to 27 are collectively shown in Table 4 below. In these Examples, the pressure during formation of the film was constantly set to 1.3 Pa; the amount of the hydrogen gas introduced (Md) was constantly set to 20 sccm; the amount of the monosilane gas introduced (Ms) was constantly set to 2 sccm; therefore the supply flow rate ratio (Md/Ms) constantly had a value of 10; the density of the high-frequency power supplied was constantly set to 0.01 W/cm³; and the plasma potential and the electron density were varied with different types of antenna used.

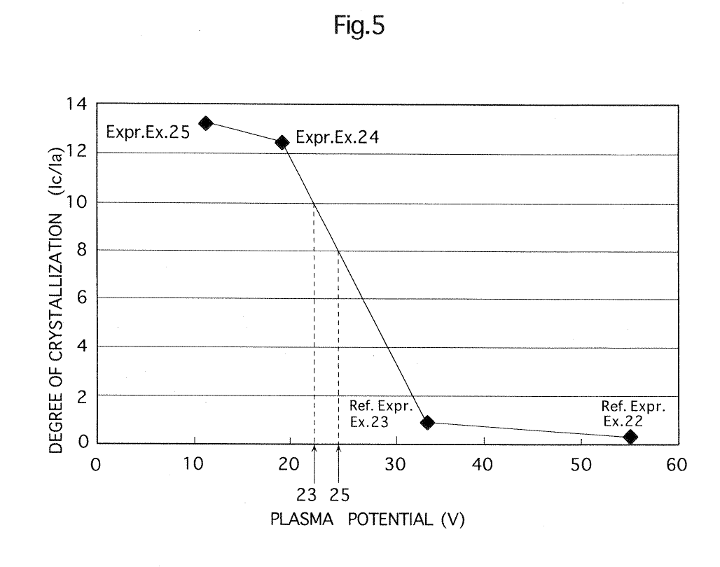

The relationships between the measurement results of the degree of crystallization (Ic/Ia) of the silicon thin films formed and the plasma potentials during formation of the films are shown in FIG. 5, and the relationships between the measurement results of the degree of crystallization (Ic/Ia) and the electron densities during formation of the films are shown in FIG. 6.

TABLE 4

| | | | Expr. | | | |
|---|---|---|---|---|---|---|
| | Ref. | Ref. | Ex. 24 | | Ref. | Ref. |
| | Expr. | Expr. | (=Expr. | Expr. | Expr. | Expr. |
| | Ex. 22 | Ex. 23 | Ex. 4) | Ex. 25 | Ex. 26 | Ex. 27 |
| Pressure during | 1.3 Pa | 1.3 Pa | 1.3 Pa | 1.3 Pa | 1.3 Pa | 1.3 Pa |
| film formation | | | | | | |
| Flow rate of | H₂ | H₂ | H₂ | H₂ | H₂ | H₂ |
| diluting gas | 20 sccm | 20 sccm | 20 sccm | 20 sccm | 20 sccm | 20 sccm |
| Flow rate of | SiH₄ | SiH₄ | SiH₄ | SiH₄ | SiH₄ | SiH₄ |
| material gas | 2 sccm | 2 sccm | 2 sccm | 2 sccm | 2 sccm | 2 sccm |
| Ratio of flow | 10 | 10 | 10 | 10 | 10 | 10 |
| rate of diluting | | | | | | |
| gas to flow rate | | | | | | |
| of material gas | | | | | | |
| High-frequency | 0.01 W/cm³ | 0.01 W/cm³ | 0.01 W/cm³ | 0.01 W/cm³ | 0.01 W/cm³ | 0.01 W/cm³ |
| power density | | | | | | |
| Plasma | 55 V | 34 V | 19 V | 11 V | 8 V | Unstable |
| potential | | | | | | |
| Electron | 5.3 × 10¹⁰/cm³ | 4.8 × 10¹⁰/cm³ | 4.4 × 10¹⁰/cm³ | 1.3 × 10¹⁰/cm³ | 3.4 × 10⁹/cm³ | Unstable |
| density | | | | | | |
| Type of | Antenna A | Antenna B | Antenna C | Antenna D | Antenna E | Antenna F |
| antenna | | | | | | |

In Experimental Examples 24, 25, silicon thin films which have been crystallized to a degree of crystallization of 8 or higher were formed.

However, in Reference Experimental Example 26, no silicon thin film which could be evaluated was accumulated on the substrate. This is because the plasma density (electron density) was lowered to such a degree that a thin film is substantially unable be formed.

In Reference Experimental Example 27, an unstable state in which plasma was ignited and extinguished was found, and no silicon thin film could be formed. This is because as a result of too low a plasma potential, maintenance of plasma itself became difficult. In Reference Experimental Examples 22, 23, Ic/Ia was significantly lowered by the damages due to the plasma.

It can be seen from FIG. 5 that if the plasma potentials during formation of the film are set within the range of 25 V or lower, Ic/Ia≧8 can be attained. Moreover, if the plasma potentials during formation of the film are set within the range of about 23 V or lower, Ic/Ia≧10 can be attained, which is more preferable.

In any case, the lower limit of the electron density is preferably about 1×10¹⁰ electrons/cm³ or higher, as already mentioned.

Experimental Examples 28, 29, in which the polycrystalline silicon thin films formed in Experimental Examples 3 to 5, 9 to 12, 17 to 19, 24 to 25, where Ic/Ia≧10 was attained, were subjected to a terminating treatment, will be described.

In both Experimental Examples 28, 29, the substrate S on which a polycrystalline silicon thin film is formed was retained by the holder 2, and high-frequency power was applied from the high-frequency power source 4 to the antenna 3 via the matching box 41. The types of antenna used are the same as those used in forming the polycrystalline silicon thin films in Experimental Examples 3 to 5, 9 to 12, 17 to 19, and 24 to 25, respectively. Moreover, an oxygen gas supply unit or a nitrogen gas supply unit was used as the gas for terminating treatment supply unit 8.

### Experimental Example 28

### Formation of Polycrystalline Silicon Thin Films Terminally Treated with oxygen)

Substrate temperature: 400° C.

Amount of oxygen gas supplied: 100 sccm

High-frequency power: 13.56 MHz 1 kw

Terminating treatment pressure: 0.67 Pa

Treating time: 1 minute

### Experimental Example 29

### Formation of Polycrystalline Silicon Thin Films Terminally Treated with Nitrogen

Substrate temperature: 400° C.

Amount of nitrogen gas supplied: 200 sccm

High-frequency power: 13.56 MHz 1 kw

Terminating treatment pressure: 0.67 Pa

Treating time: 5 minutes

The polycrystalline silicon-based thin film which has been terminally treated with oxygen or nitrogen in this manner was used as a semiconductor film for TFTs. The electron mobility as a TFT electrical characteristic was further improved and the OFF-current was reduced than in the case where no terminating treatment was conducted.

Although the deposition chamber 1 was used as a terminally treating chamber in the terminating treatment described above, a separate terminally treating chamber may be provided, in which this terminating treatment may be carried out. For example, after a polycrystalline silicon-based thin film is formed in the deposition chamber 1, the substrate S on which the polycrystalline silicon-based thin film is formed may be loaded into a terminally treating chamber which is in communication with the deposition chamber 1 (directly or indirectly, e.g., via a transferring chamber having a goods transferring robot), and a terminating treatment may be carried out in the terminally treating chamber.

Examples of formation of the polycrystalline silicon thin film have been described above, but the present invention can be also applied for forming a polycrystalline silicon-based thin film mainly composed of germanium-containing silicon, and a polycrystalline silicon-based thin film mainly composed of carbon-containing silicon.

Experimental Example of such thin film formation will be described below.

### Experimental Example 30

### Formation of Germanium-Containing Polycrystalline Silicon-Based Thin Film)

Substrate: Non-alkali glass substrate

Substrate temperature: 400° C.

Film-forming material gas: SiH₄ (2 sccm) and GeH₄ (0.02 sccm)

Diluting gas: hydrogen gas 20 sccm

Gas supply flow rate ratio, H₂/(SiH₄+GeH₄): 9.9

Deposition pressure: 1.3 Pa

High-frequency power density: 0.01 W/cm³

Plasma potential: 19 V

Electron density: 4.5×10¹⁰ electrons/cm³

Type of antenna: C

### Experimental Example 31

### Formation of Carbon-Containing Polycrystalline Silicon-Based Thin Film)

Substrate: Non-alkali glass substrate

Substrate temperature: 400° C.

Film-forming material gas: SiH₄ (2 sccm) and CH₄ (0.02 sccm)

Diluting gas: Hydrogen gas 20 sccm

Gas supply flow rate ratio H₂/(SiH₄+CH₄): 9.9

Deposition pressure: 1.3 Pa

High-frequency power density: 0.01 W/cm³

Plasma potential: 19 V

Electron density: 4.4×10¹⁰ electrons/cm³

Type of antenna: C

According to Experimental Example 30, the amount of germanium contained in the film was about 1 atm % (1 atomic %). In addition, in the evaluation of the degree of crystallization of silicon in the film by the laser Raman scattering spectroscopy, a polycrystalline silicon-based thin film in which the ratio (Ic/Ia) of the Raman scattering peak intensity Ic at a wave number of 520⁻¹ cm or therearound derived from the crystallized silicon component to the Raman scattering intensity Ia at a wave number of 480⁻¹ cm derived from the amorphous silicon component was 12.3 could be confirmed.

According to Experimental Example 31, the amount of carbon contained in the film was about 1 atm % (1 atomic %). In addition, in the evaluation of the degree of crystallization of silicon in the film, a polycrystalline silicon-based thin film in which the ratio (Ic/Ia) of the Raman scattering peak intensity Ic at a wave number of 520⁻¹ cm or therearound derived from the crystallized silicon component to the Raman scattering intensity Ia at a wave number of 480⁻¹ cm derived from the amorphous silicon component was 12.4 was confirmed.

The films formed in Experimental Examples 30, 31 were subjected to a terminating treatment under the conditions similar to those in Experimental Examples 28, 29, and were used as semiconductor films for TFTs. In these cases, the electron mobility as a TFT electrical characteristic was further improved, and the OFF-current was reduced than in the case where no terminating treatment was conducted.

### INDUSTRIAL APPLICABILITY

The present invention can be used to form, on a deposition target substrate, a polycrystalline silicon-based thin film which can be utilized as a material for a TFT (thin film transistor) switch or for producing various kinds of integrated circuits, solar cells and the like as a semiconductor film.

1. A method for forming a silicon-based thin film by a plasma CVD, comprising introducing, of a film-forming material gas containing silicon atoms and a diluting gas, at least the film-forming material gas into a deposition chamber; generating plasma from the introduced gas by high-frequency excitation; and forming a silicon-based thin film in the plasma on a deposition target substrate disposed in the deposition chamber, the film being formed in a state that pressure inside the deposition chamber during formation of the film is selected and determined in a range from 0.0095 Pa to 64 Pa; ratio (Md/Ms) of a supply flow rate Md [sccm] of the diluting gas to a supply flow rate Ms [sccm] of the film-forming material gas introduced into the deposition chamber during formation of the film is selected and determined in a range from 0 to 1200; high-frequency power density during formation of the film is selected and determined in a range from 0.0024 W/cm³ to 11 W/cm³; plasma potential during formation of the film is maintained at 25 V or lower; and electron density in the plasma during formation of the film is maintained to 1×10¹⁰ electrons/cm³ or higher, and
in such a state that combination of the pressure inside the deposition chamber during formation of the film thus selected and determined, the supply flow rate ratio (Md/Ms) of the film-forming material gas to the diluting gas, the high-frequency power density, the plasma potential to be maintained and the electron density in plasma is such a combination that allows formation of a polycrystalline silicon-based thin film having a ratio (Ic/Ia=degree of crystallization) of Raman scattering peak intensity Ic derived from a crystallized silicon component to Raman scattering peak intensity Ia derived from an amorphous silicon component in crystallizability evaluation of silicon in the film determined by a laser Raman scattering spectroscopy of 8 or higher.

2. The method for forming a silicon-based thin film according to claim 1, wherein generating plasma from the gas introduced into the deposition chamber by high-frequency excitation is carried out by applying high-frequency power to the introduced gas from an antenna of inductive coupling type placed in the deposition chamber.

3. The method for forming a silicon-based thin film according to claim 1 or 2, in which Raman scattering intensity at a wave number of 480⁻¹ cm is employed as the Raman scattering peak intensity Ia derived from the amorphous silicon component, and Raman scattering peak intensity at a wave number of 520⁻¹ cm or therearound is employed as the Raman scattering peak intensity Ic derived from the crystallized silicon component.

4. The method for forming a silicon-based thin film according to claim 1 or 2, wherein a gas containing silicon atoms and also containing germanium atoms is employed as the film-forming material gas containing silicon atoms to form a polycrystalline silicon-based thin film containing germanium.

5. The method for forming a silicon-based thin film according to claim 1 or 2, wherein a gas containing silicon atoms and also containing carbon atoms is employed as the film-forming material gas containing silicon atoms to form a polycrystalline silicon-based thin film containing carbon.

6. The method for forming a silicon-based thin film according to claim 1 or 2, wherein after the polycrystalline silicon-based thin film is formed, the surface of the polycrystalline silicon-based thin film is subjected to a terminating treatment in plasma for terminating treatment produced by applying high-frequency power to at least one gas for terminating treatment selected from an oxygen-containing gas and a nitrogen-containing gas.

7. The method for forming a silicon-based thin film according to claim 6, wherein after the polycrystalline silicon-based thin film is formed in the deposition chamber, the substrate on which the polycrystalline silicon-based thin film is formed is loaded into a terminally treating chamber which is in communication with the deposition chamber, and is subjected to the terminating treatment in the terminally treating chamber.
